(19) United States
(12) Patent Application Publication
(10) Pub. No.: US 2011/0214730 A1
(43) Pub. Date: Sep. 8, 2011

(54) DYE-SENSITIZED SOLAR CELL

(75) Inventors: Kunpei Kobayashi, Tachikawa-shi (JP); Mikio Baba, Ome-shi (JP); Norihiro Arai, Hino-shi (JP)

(73) Assignee: CASIO COMPUTER CO., LTD., Tokyo (JP)

(21) Appl. No.: 13/038,508

(22) Filed: Mar. 2, 2011

(30) Foreign Application Priority Data
Mar. 4, 2010 (JP) 2010-048286
Mar. 25, 2010 (JP) 2010-070574

(51) Int. Cl. H01L 31/0224; H01L 31/0236

(52) U.S. Cl. 136/256

(57) ABSTRACT

A dye-sensitized solar cell includes a first electrode, a second electrode, an electron-collector/dye layer, and an electron donor. The second electrode faces the first electrode. The electron-collector/dye layer provided on the first electrode includes an electron collector and dye. The electron collector includes first electron collector grains and second electron collector grains. The first electron collector grains have a diameter or diameters within a first diameter range and the second electron collector grains have a diameter or diameters within a second diameter range. A minimum value of the second diameter range is greater than a maximum value of the first diameter range. The electron donor is provided between the electron-collector/dye layer and the second electrode.

### CROSS-REFERENCE TO RELATED APPLICATIONS

This application is based upon and claims the benefit of priority from prior Japanese Patent Applications No. 2010-048286, filed Mar. 4, 2010; and No. 2010-070574, filed Mar. 25, 2010, the entire contents of both of which are incorporated herein by reference.

### BACKGROUND OF THE INVENTION

1. Field of the Invention

The present invention relates to a dye-sensitized solar cell

2. Description of the Related Art

Recent attention has focused on solar cells which utilize clean, inexpensive natural energy without damaging the environment. Although a solar cell using silicon crystal has already been put into practical use, manufacturing the cell involves high energy costs. In contrast a dye-sensitized solar cell, for example, as disclosed in Jpn. Pat. Appln. KOKAI 2008-41258, can be manufactured with a large-area element at lower cost than a solar cell using silicon crystal, and further is capable of achieving a flexible cell.

When a dye-sensitized solar cell is irradiated with light, dye molecules which have absorbed the light are excited, and electrons of the dye molecules are injected into titanium oxide, which is a semiconductor. On the other hand, dye molecules are supplied, from electrolyte, with electrons equivalent in amount to lost electrons. Therefore, a potential difference occurs between the titanium oxide and the electrolyte. The potential difference is used for a cell.

In the dye-sensitized solar cell, a set of titanium oxide grains having a grain diameter as small as 20 nm is used as a component which receives electrons discharged from the excited dye molecules. One of reasons why the titanium oxide grains have such a small grain diameter is that the grains must make contact with a large number of dye molecules. The roughness factor (RF=actual surface area/projection area) of a titanium oxide film including the grains is required to be 1,000 or more. In order to obtain sufficient output, the thickness of the film including the grains and the dye molecules must be 10 μm or more.

Thus, in the dye-sensitized solar cell, a thick film is formed of very small grains, and therefore, coupling between the grains made of titanium oxide is easily deteriorated. In addition, the assembled dye molecules easily enter into between the grains. Therefore, the resistance of electrical connection channels formed by the grains increases, i.e., the internal resistance increases. As a result, there is a problem that generating efficiency of the solar cell deteriorates.

### BRIEF SUMMARY OF THE INVENTION

The present invention is directed to providing a dye-sensitized solar cell with high generating efficiency.

According to an aspect of the invention, a dye-sensitized solar cell includes a first electrode; a second electrode which faces the first electrode; an electron-collector/dye layer provided on the first electrode, the electron-collector/dye layer including an electron collector and dye, the electron collector comprising first electron collector grains which have a diameter or diameters within a first diameter range and second electron collector grains which have a diameter or diameters within a second diameter range, a minimum value of the second diameter range being greater than a maximum value of the first diameter range; and an electron donor provided between the electron-collector/dye layer and the second electrode.

According to another aspect of the invention, a dye-sensitized solar cell includes a first substrate; a second substrate which faces the first substrate; a first electrode formed on a first surface of the first substrate, the first surface facing a second surface of the second substrate; an electron-collector/dye layer provided on the first electrode; a catalyst layer provided on the second surface, the catalyst layer having a diffusion/reflection surface which faces the first surface; and an electrode donor provided between the electron-collector/dye layer and the catalyst layer.

According to another aspect of the invention, a dye-sensitized solar cell includes a first electrode; a second electrode which faces the first electrode; an electron-collector/dye layer including an electron collector and dye which are provided on a first surface of the first electrode, the first surface facing a second surface of the second electrode; a catalyst layer provided on the second surface, the catalyst layer having a diffusion/reflection surface which facing the first surface; and an electron donor provided between the electron-collector/dye layer and the catalyst layer.

According to the invention, generating efficiency can be improved.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing an example configuration of a dye-sensitized solar cell according to a first embodiment of the invention;

FIG. 2 is a schematic view showing an example configuration of a part including an electrode, an electron collector, and dye of the dye-sensitized solar cell according to the first embodiment of the invention;

FIG. 3 is an energy diagram for explaining the principle generating electricity with the dye-sensitized solar cell according to the first embodiment of the invention;

FIG. 4A is a graph showing a case of a comparative example, for explaining electron transfer efficiency of the dye-sensitized solar cell according to the first embodiment of the invention;

FIG. 4B is a graph showing a case of the first embodiment, for explaining electron transfer efficiency of the dye-sensitized solar cell according to the first embodiment of the invention;

FIG. 5 is a sectional view showing an example configuration of a dye-sensitized solar cell according to a second embodiment of the invention;

FIG. 6A is a plan view showing an example of a surface shape of a second substrate of the dye-sensitized solar cell according to the second embodiment of the invention;

FIG. 6B is a perspective view showing an example of the surface shape of the second substrate of the dye-sensitized solar cell according to the second embodiment of the invention;

FIG. 7 is a view showing a schematic example of a structure formed on the second substrate of the dye-sensitized solar cell according to the second embodiment of the invention; and

FIG. 8 is a graph showing an example of current-voltage curves of the dye-sensitized solar cell according to the second embodiment and a comparative example.

### DETAILED DESCRIPTION OF THE INVENTION

### First Embodiment

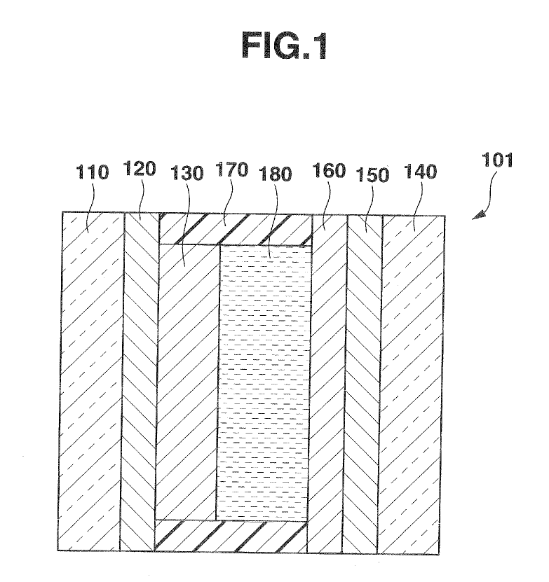

A first embodiment of the present invention will now be described with reference to the drawings. In a dye-sensitized solar cell 101 according to the first embodiment, a transparent conductive film 120 as a first electrode made of indium tin oxide (ITO) or fluorine-doped tin oxide (FTO) is formed on a transparent first substrate 110 made of, for example, glass or a film, as shown in FIG. 1. The transparent conductive film 120 may be patterned. A current collector pattern made of silver may be provided as a layer above or below the transparent conductive film 120. An electron-collector/dye layer 130 is formed on the transparent conductive film 120. The electron-collector/dye layer 130 will be described in details later.

A conductive film 150 as a second electrode is formed on a transparent second substrate 140 which is made of, for example, glass or a film and opposed to the first substrate 110. A catalyst layer 160 made of platinum or carbon is formed on the conductive film 150.

The first substrate 110 is opposed to the second substrate 140 in a manner that a surface where the electron-collector/dye layer 130 is formed is opposed to the catalyst layer 160 of the second substrate 140. The first substrate 110 is bonded to the second substrate 140 at peripheral parts of the opposed surfaces by a seal material 170 so as to maintain, for example, a gap of about 10 to 50 μm maintained from the second substrate 140. An electron donor 180 which is an electrolyte is enclosed in the gap.

For example, acetonitrile, methoxyacetonitrile, or ethylene carbonate can be used as a solvent for the electron donor 180. For example, 1,2-dimethyl-3-n-propylimidazolium iodide (DMPImI), lithium iodide (LiI), iodine (I₂), or 4-tert-butylpyridine (TBP) can be used as a solute for the electron donor 180.

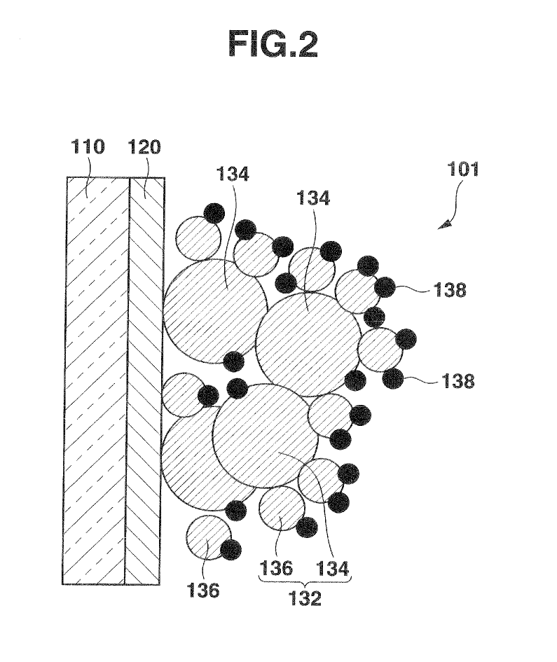

The electron-collector/dye layer 130 will now be described in details. The electron-collector/dye layer 130 comprises an electron collector 132 made of, for example, anatase titanium oxide, and dye 138 made of, for example, ruthenium dye (e.g., N719 dye), as shown in FIG. 2. The electron collector 132 comprises electron transfer grains (second electron collector grains) 134 and dye absorption grains (first electron collector grains) 136. The electron transfer grains 134 are formed as electron collector grains 132 with a relatively large grain diameter. The dye absorption grains 136 are formed as electron collector grains 132 with a relatively small grain diameter.

The electron collector 132 is not limited to titanium oxide but may be, for example, zinc oxide, tin oxide, tungsten oxide, niobium oxide, indium oxide, or a compound thereof. The first embodiment will be described supposing use of titanium oxide (TiO₂).

The dye 138 is not limited to N719 dye but may be, for example, N3 dye or black dye as ruthenium-based dye, as well as may be D149, xanthene, PVK, merocyanine, or oxazine as pure organic dye.

As shown in FIG. 2, the electron transfer grains 134 are in contact with adjacent ones of themselves, and are partially in contact with the transparent conductive film 120. The dye absorption grains 136 are in contact with the electron transfer grains 134. The dye 138 is absorbed by the electron transfer grains 134 and dye absorption grains 136. In this configuration, the electron transfer grains 134 mainly function to transfer electrons discharged from the dye 138 to the transparent conductive film 120. The dye absorption grains 136 function to enhance a surface area of the electron collector 132 in order to absorb as much dye 138 as possible.

Preferably, the dye absorption grains 136 have a diameter between 5 nm and 25 nm, and the electron transfer grains 134 have a diameter between 100 nm and 400 nm. A minimum value of a diameter range of the electron transfer grains 134 is greater than a maximum value of a diameter range of the dye absorption grains 136. Preferably, weight ratios of the dye absorption grains 136 and the electron transfer grains 134 are 20 to 25% and 75 to 80%, respectively. The electron-collector/dye layer 130 formed of the electron transfer grains 134, dye absorption grains 136, and dye 138 has a thickness of, for example, about 10 μm.

The electron-collector/dye layer 130 can be prepared in a manner as follows. Anatase titanium oxide grains of two grain diameters as the electron transfer grains 134 and dye absorption grains 136 are mixed and made into paste. The paste is printed or coated on the first substrate 110. Thereafter, the paste on the first substrate 110 is sintered to form a titanium oxide film. After forming the titanium oxide film, the titanium oxide film is further soaked in a liquid of the dye 138 solved in an organic solvent, resulting in that the dye 138 is absorbed into titanium oxide. The electron-collector/dye layer 130 is thus prepared.

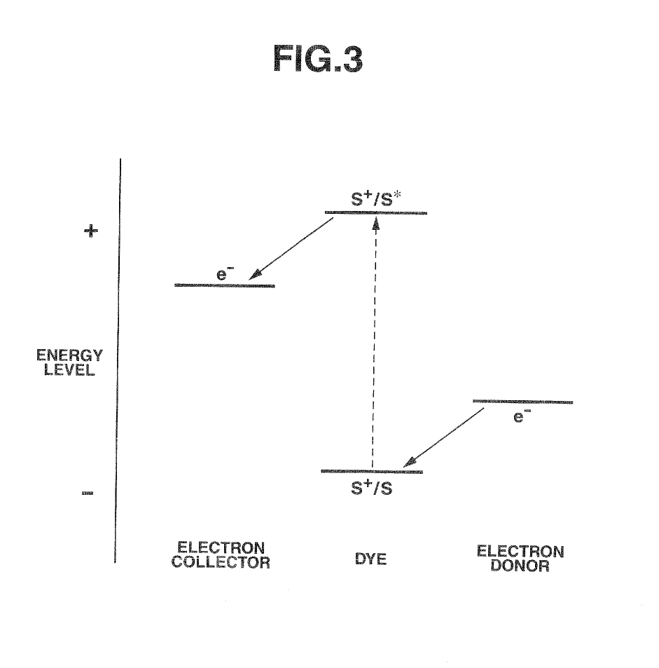

The principle of generating electricity with the dye-sensitized solar cell 101 according to the first embodiment will now be described with reference to FIG. 3. When light enters into the dye-sensitized solar cell 101 from a side of the first substrate 110, the light is absorbed by the dye 133. The light absorbed by the dye 138 excites the dye 138 (as denoted by an dashed arrow). Electrons of the excited dye 138 are transferred to the electron collector 132 made of, for example, titanium oxide which is a wide gap semiconductor. That is, the dye 138 is oxidized. Electrons received by the electron collector 132 move to the transparent conductive film 120. On the other hand, the dye 138 which has lost electrons is supplied with electrons from, for example, I⁻ of the electron donor 180 in contact with the conductive film 150 which comprises the catalyst layer 160. That is, the dye 138 is reduced by the electron donor 180. 3I⁻ supplies the dye 138 with electrons and then becomes I₃⁻. Accordingly, for example, I₃⁻ of the electron donor 180 is going to receive electrons from the conductive film 150. At this time, a potential difference occurs between the transparent conductive film 120 and the conductive film 150. If an external circuit is connected between the transparent conductive film 120 and the conductive film 150, the electrons which have moved to the transparent conductive film 120 move to the conductive film 150 through the external circuit. These electrons move to, for example, I₃⁻ of the electron donor 180, which then becomes 3I⁻. The dye 138 which has lost electrons is supplied with electrons from, for example, I⁻ of the electron donor 180. By thus connecting an external circuit between the transparent conductive film 120 and the conductive film 150, the external circuit can extract a current from the dye-sensitized solar cell, according to the present embodiment.

The dye 138 in an excited state has a higher energy level than the electron collector 132. The dye 138 in a ground state has a lower energy level than the electron donor 180.

### Example

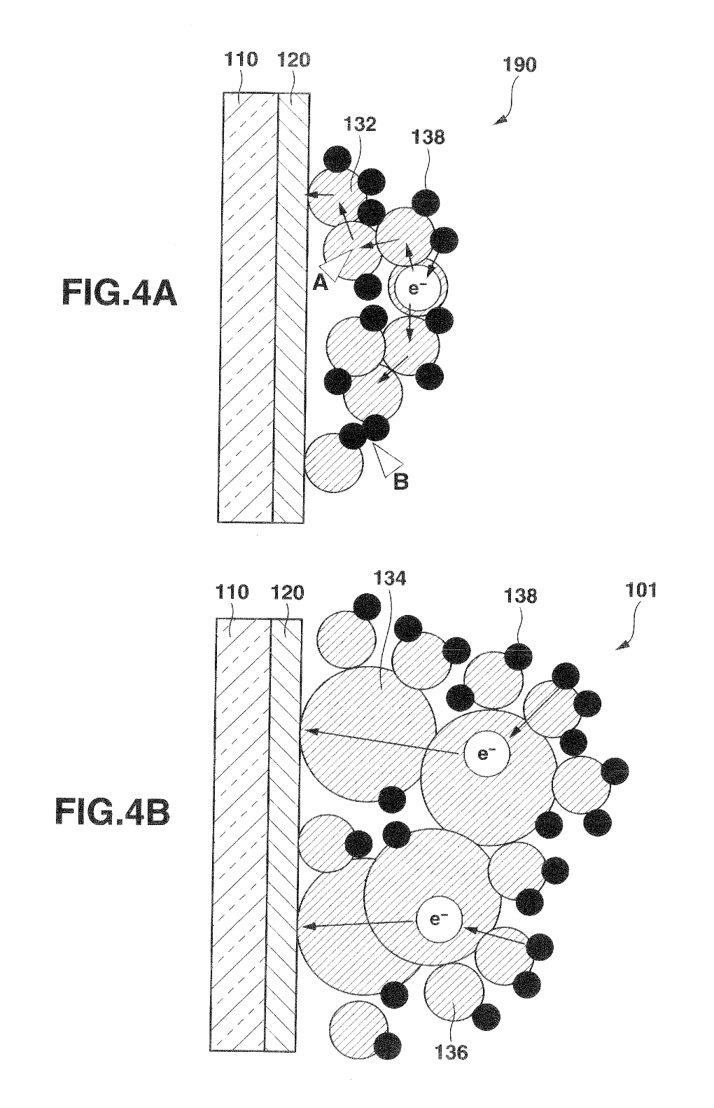

An example of the dye-sensitized solar cell 101 according to the first embodiment will now be described below. Characteristics of the dye-sensitized solar cells 101 and that of dye-sensitized solar cells 190 were compared with each other. The dye-sensitized solar cells 101 is the dye-sensitized solar cell according to the present embodiment used titanium oxide as electron collectors 132 having two different diameters respectively for the electron transfer grains 134 and dye absorption grains 136 (FIG. 43). The dye-sensitized solar cells 190 is a dye-sensitized solar cell as a comparative example used titanium oxide as an electron collector 132 having one diameter (FIG. 4A). Comparison was made about a fill factor (FF) value which is the ratio of actual power to apparent maximum power.

In the present example, an averaged diameter of titanium oxide as the electron transfer grains 134 was set to 100 nm, and an averaged diameter of titanium oxide as the dye absorption grains 136 was set to 10 nm. That is, the electron transfer grains 134 and dye absorption grains 136 are made of the same material as each other, and respectively have different diameters which differ from each other by one digit or 10 times or more. Where mixing ratios of the electron transfer grains 134 and dye absorption grains 136 are expressed as weight percent, mixing ratios of the electron transfer grains 134 and dye absorption grains 136 were set to 75% and 25%, respectively. An averaged thickness of the electron-collector/dye layer 130 comprising the electron transfer grains 134, dye absorption grains 136, and dye 138 was set to 5 μm.

On the other hand, in the dye-sensitized solar cell 190 as the comparative example for reference, the electron collector 132 included only titanium oxide having an averaged diameter of 10 nm. Other conditions were the same as those for the present embodiment. When only the diameter of titanium oxide grains included in the electron collector 132 was increased, the roughness factor simply decreased, and therefore, the averaged thickness of the electron-collector/dye layer 130 had to be increased by an amount corresponding to the decrease in the roughness factor. In this case, absorption of visible light increases undesirably for practical use.

FP values were measured for the dye-sensitized solar cell 101 of the present embodiment and the dye-sensitized solar cell 190 of the comparative example, according to Japanese Industrial Standard JIS C 8914 “Measuring method of output power for crystalline solar PV modules,” the entire contents of which are incorporated herein by reference. In brief, current I-voltage V curves were obtained by irradiation with light having a wavelength of 400 to 1,100 nm at a luminous intensity of 1,000 W/m². From the obtained I-V curves each, a FF value was obtained by dividing a maximum output by a product of an open voltage and a short-circuit current. As this FF value increases, internal loss of a corresponding dye-sensitized solar cell decreases, i.e., generating efficiency increases.

The FF value was measured three times for each of the present embodiment and the comparative example. As a result, the FF values were 44.1±1.3 (mean±standard deviation) for the dye-sensitized solar cell 101 according to the embodiment, and 25.6±0.3 (mean±standard deviation) for the dye-sensitized solar cell 190 according to the comparative example. That is, the FF value of the present embodiment increased by 74% compared with the comparative example.

Such a difference is considered to result from the following reason. As shown in FIG. 4A, in the comparative example, electrons e⁻ discharged from the dye 138 are transferred to the transparent conductive film 120 through grains having a small diameter which constitute the electron collector 132 (denoted by a white arrowhead A in FIG. 4A). Accordingly, electrons e⁻ must pass over a large number of coupling parts of the grains in the electron collector 132. Therefore, the resistance of electrical connection channels formed in the electron collector 132 increases and hinders electrons from being transferred. Also in the comparative example, molecules of the dye 138 meet each other and enter into the space between the grains which are included in the electron collector 132, thereby forming parts in which the grains included in the electron collector 132 are not in contact with each other (denoted by a white arrowhead B in FIG. 4A) in some cases. The parts where the grains included in the electron collector 132 are not in contact with each other do not transfer electrons e⁻.

In contrast in the present embodiment as shown in FIG. 4B, electrons e⁻ discharged from the dye 138 are transferred to the transparent conductive film 120 through a small number of electron transfer grains 134 having a large diameter. Accordingly, there are less coupling parts which electrons e⁻ are to pass. Since the electron transfer grains 134 have a large diameter and accordingly a large surface area per grain, coupling between the electron transfer grains 134 each other is achieved excellently. Therefore, the resistance of electrical connection channels formed in the electron collector 132 is lower than in the case of FIG. 4A, and electrons are easily transferred. Since there are a large number of dye absorption grains 136, total surface area increases and the roughness factor (RE) is 1,000 or more, which is considered to be the value required for a dye-sensitized solar cell. Therefore, a satisfactory number of molecules of dye 138 are absorbed by the electron collector 132.

From the reason above, electrons e⁻ discharged from the satisfactory number of molecules of dye 138 are smoothly transferred to the transparent conductive film 120, according to the present embodiment. As a result, the present embodiment can increase the FF value, compared with the comparative example.

As has been described above, the dye-sensitized solar cell 101 according to the first embodiment uses, as the electron collector 132, the electron transfer grains 134 and the dye absorption grains 136 which respectively have different grain diameters. Therefore, resistance for the transferring of electrons from the dye 138 to the transparent conductive film 120 is reduced. Accordingly, electrons are transferred smoothly and a satisfactory surface area is obtained. A satisfactory number of molecules of dye 138 can therefore be absorbed by the electron collector 132. As a result, the FF value can be improved. That is, internal loss of the dye-sensitized solar cell is reduced, and generating efficiency is improved.

### Second Embodiment

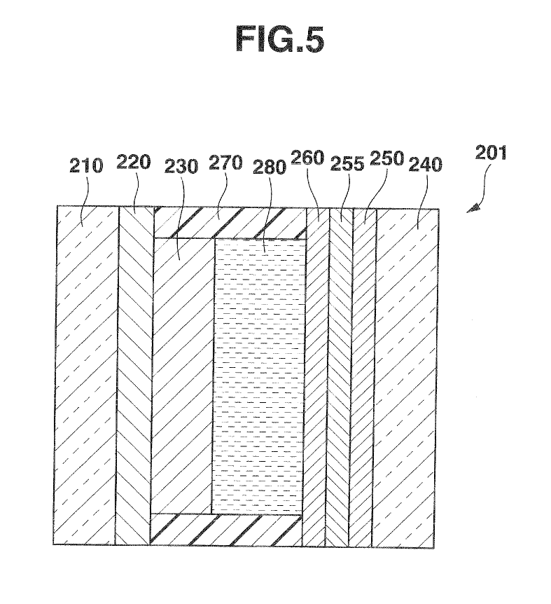

A second embodiment of the present invention will now be described below with reference to the drawings. In a dye-sensitized solar cell 201 according to the second embodiment, a transparent conductive film 220 as a first electrode made of indium tin oxide (ITO) or fluorine-doped tin oxide (FTO) is formed on a surface (a first surface) of a transparent first substrate 210 made of, for example, glass or a film, as shown in FIG. 5. The transparent conductive film 220 may be patterned. A current collector pattern made of silver may also be provided as a layer above or below the transparent conductive film 220. An electron-collector/dye layer 230 is formed on the transparent conductive film 220. The electron-collector/dye layer 230 will be described in details later.

The electron-collector/dye layer 230 comprises an electron collector including grains of, for example, anatase titanium oxide, and dye made of, for example, ruthenium dye (e.g., N719 dye). The electron collector has a diameter of, for example, about 20 nm. The electron collector is not limited to titanium oxide but may be, for example, zinc oxide, tin oxide, tungsten oxide, niobium oxide, indium oxide, or a compound thereof. The second embodiment will be described supposing use of titanium oxide (TiO₂).

The dye is not limited to N719 dye but may be, for example, N3 dye or black dye as ruthenium-based dye, as well as may be D149, xanthene, PVK, merocyanine, or oxazine as pure organic dye. The dye functions to absorb light and discharge electrons.

On the other hand, a conductive film 250 as a second electrode is formed on a transparent second substrate 240 which is made of, for example, glass or a film and opposed to the first substrate 210. A catalyst layer 260 made of platinum or carbon is formed on the conductive film 250. In place of forming the conductive film 250, the catalyst layer 260 made of platinum and formed on the second substrate 240 can cover a function of the conductive film 250. In the example shown in FIG. 5, a foundation layer 255 is provided between the conductive film 250 and the catalyst layer 260.

In the second embodiment, light enters into the dye-sensitized solar cell 201 from a side of the first substrate 210, and penetrates the electron-collector/dye layer 230. The light is then diffused and reflected for reuse in order to improve generating efficiency. Therefore, a surface of the catalyst layer 260 forms a diffusion/reflection surface. Accordingly, a surface of the second substrate 240 (a second surface) is formed to have fine roughness. The roughness may be formed, for example, by a chemical method such as frosting or etching using a solution or by a physical method such as sandblast. A diffusion/reflection surface is formed by forming the conductive film 250 and the catalyst layer 260 made of platinum, on the second substrate 240 where fine roughness is formed.

In place of grinding the second substrate 240 to have roughness, a similar diffusion/reflection surface can be formed in a manner of producing roughness by forming an organic diffusion film on a flat glass surface.

The first substrate 210 is opposed to the second substrate 240 in a manner that a surface where the electron-collector/dye layer 230 is formed is opposed to the catalyst layer 260 of the second substrate 240. The first substrate 210 is bonded to the second substrate 240 at peripheral parts of the opposed surfaces by a seal material 270 so as to maintain, for example, a gap of about 10 to 50 μm from the second substrate 240. An electron donor 280 which is an electrolyte is enclosed in the gap.

For example, acetonitrile, methoxyacetonitrile, or ethylene carbonate can be used as a solvent for the electron donor 280. For example, 1,2-dimethyl-3-n-propylimidazolium iodide (DMPImI), lithium iodide (LiI), iodine (I₂), or 4-tert-butylpyridine (TBP) can be used as a solute for the electron donor 280.

The principle of generating electricity with the dye-sensitized solar cell 201 according to the second embodiment is the same as that for the dye-sensitized solar cell 101 according to the first embodiment, which has been described with reference to FIG. 3. Further descriptions of the principle will therefore be omitted.

### Example

An example of the dye-sensitized solar cell 201 according to the second embodiment will now be described. In a dye-sensitized solar cell 201 according to the present embodiment, fine roughness was formed on a second substrate 240, and a surface of a catalyst layer 260 was formed as a diffusion/reflection surface. The dye-sensitized solar cell 201 of the present embodiment was compared with a dye-sensitized solar cell 290 as a comparative example in which a second substrate 240 was formed to be a flat surface and a surface of a catalyst layer 260 was formed to be a mirror surface. An index used for comparison was conversion efficiency η as a ratio of energy of generated electricity to energy of incident light.

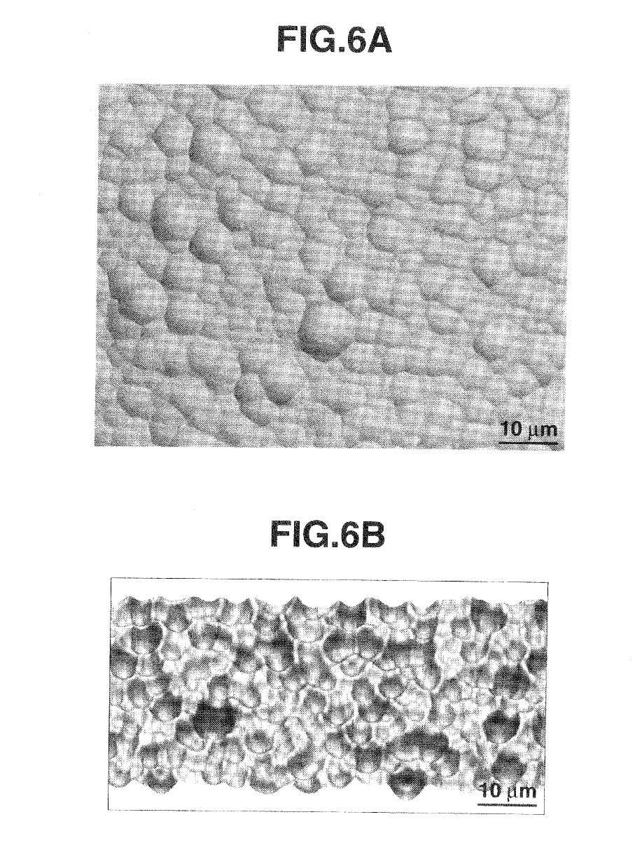

In the dye-sensitized solar cell 201 according to the present embodiment, roughness was formed on the second substrate 240 by chemical polishing. A surface shape of the second substrate 240 which was formed to be rough is shown in FIGS. 6A and 6B. FIG. 6A is a plan view, and FIG. 6B is a perspective view. With respect to the rough surface, a center line average roughness Ra was 0.137 μm, and ten point height of irregularities Rz was 0.692 μm. The average roughness Ra expresses a value obtained in the following manner. That is, a reference length is extracted, and a roughness curve is folded back from the center line. An area of a part surrounded by the roughness curve and the center line was divided by the reference length, to obtain the averaged roughness Ra. The ten point height of irregularities Rz expresses a value of difference between an averaged value of heights of five highest crests within a reference length of a sectional curve and an averaged value of depths of five deepest troughs. Ra is preferably 0.14±0.1 μm, and Rz is preferably 0.7±0.3 μm.

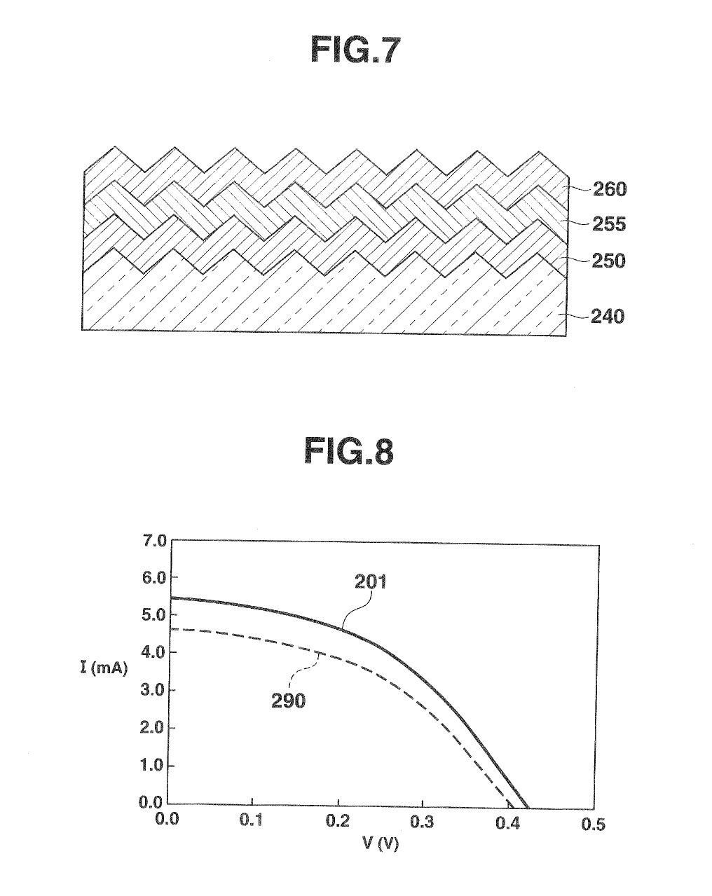

On the rough surface of the second substrate 240, a conductive film 250 made of ITO was formed as shown in FIG. 7. A foundation layer 255 was formed by forming a film of titanium on the conductive film 250. A catalyst layer 260 was formed by forming a film of platinum on the foundation layer 255. A surface of the platinum film forming the catalyst layer 260 served as a diffusion/reflection surface by forming the surface to have roughness which corresponded to roughness of the surface of the second substrate 240 through the conductive film 250 and foundation layer 255. The foundation layer 255 has an effect of increasing a surface area of platinum forming the catalyst layer 260.

On the other hand, a transparent conductive film 220 made of ITO was formed on a first substrate 210 made of glass. Anatase titanium oxide having a grain diameter 20 nm was screen-printed on the transparent conductive film 220, so to have a shape of 30 mm square and a film thickness or about 2 μm. A heat treatment is performed thereon, to form an electron collector. D149 dye which forms dye was adsorbed by the electron collector. In this manner, an electron-collector/dye layer 230 was formed.

Next, a second substrate 240 where a catalyst layer 260 was formed, and the first substrate 210 where the electron-collector/dye layer 230 was formed were bonded and sealed to each other at an interval of 10 μm maintained therebetween. Thereafter, an iodine electrolytic solution as an electron donor 280 was injected by vacuum injection and sealed. The dye-sensitized solar cell 201 was thus prepared.

In the dye-sensitized solar cell 290 as the comparative example, no roughness was formed on the second substrate 240. Other features of a configuration were the same as those of the dye-sensitized solar cell 201 according to the present embodiment.

Values of conversion efficiency η were measured for the dye-sensitized solar cell 201 of the present embodiment and the dye-sensitized solar cell 190 of the comparative example, according to Japanese Industrial Standard JIS C 8914, “Measuring method of output power for crystalline solar PV modules”. In brief, current vs. voltage (I-V) curves were obtained by irradiation with light having a wavelength of 400 to 1,100 nm at a luminous intensity of 1,000 W/m². From the obtained I-V curves each, a value of conversion efficiency η was obtained. As the value of conversion efficiency η increases, the efficiency of converting luminous energy into electrical energy improves, i.e., generating efficiency increases.

The obtained I-V curves are shown in FIG. 8. In this figure, a curve of a solid line expresses an I-V curve of the dye-sensitized solar cell 201 according to the present embodiment, and a curve of a broken line expresses an I-V curve of the dye-sensitized solar cell 290 according to the comparative example. As shown in the figure, the I-V curve of the dye-sensitized solar cell 201 according to the present embodiment positions in an upper right side of the graph. This means that the efficiency of conversion from luminous energy into electrical energy is excellent. The conversion efficiency η of the dye-sensitized solar cell 201 according to the present embodiment is 0.117%, and the conversion efficiency η of the dye-sensitized solar cell 290 according to the comparative example is 0.096%. That is, the conversion efficiency η of the present embodiment is 1.23 times that of the comparative example.

The following is considered as a reason for the higher conversion efficiency η of the present embodiment than the comparative example. Light, which has entered from a side of the first substrate 210 and has not been absorbed by dye in the electron-collector/dye layer 230, is reflected on a surface of the catalyst layer 260 and enters again into the electron-collector/dye layer 230. At this time, since a surface of the catalyst layer 260 in the comparative example is a mirror surface, the reflected light travels linearly, and a light path for the light to penetrate the electron-collector/dye layer 230 is short. Therefore, most of the light is not absorbed but passes, although the light is partially absorbed by the dye. In contrast, since the surface of the catalyst layer 260 in the present embodiment is a diffusion/reflection surface, the light is diffused and reflected so that a light path for the light to penetrate the electron-collector/dye layer 230 is long. Therefore, the ratio of light absorbed by dye can be increased to be higher than in the comparative example. Accordingly, the conversion efficiency η can be improved.

As described above, in the dye-sensitized solar cell 201 according to the second embodiment, a surface of the catalyst layer 260 forms a diffusion/reflection surface. Therefore, a ratio of light absorbed by dye increases to be higher than when the surface of the catalyst layer 260 forms a mirror surface. That is, the second embodiment is capable of improving generating efficiency of the dye-sensitized solar cell 201.

As in the first embodiment, the dye-sensitized solar cell 201 according to the second embodiment may also be configured to use two types of grains which respectively have different grain diameters, as the electron collector used for the electron-collector/dye layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A dye-sensitized solar cell comprising:
a first electrode;
a second electrode which faces the first electrode;
an electron-collector/dye layer provided on the first electrode, the electron-collector/dye layer including an electron collector and dye, the electron collector comprising first electron collector grains which have a diameter or diameters within a first diameter range and second electron collector grains which have a diameter or diameters within a second diameter range, a minimum value of the second diameter range being greater than a maximum value of the first diameter range; and
an electron donor provided between the electron-collector/dye layer and the second electrode.

2. The dye-sensitized solar cell of claim 1, wherein
the first electron collector grains are configured to absorb the dye, and
the second electron collector grains are configured to transfer electrons discharged from the dye to the first electrode.

3. The dye-sensitized solar cell of claim 2, wherein the second electron collector grains have an average diameter which is ten times or more greater than an average diameter of the first electron collector grains.

4. The dye-sensitized solar cell of claim 2, wherein
the first diameter range is from 5 nm to 25 nm, and
the second diameter range is from 100 nm to 400 nm.

5. The dye-sensitized solar cell of claim 2, wherein the electron collector comprises the first electron collector grains at a ratio of 20 to 25 weight percent.

6. The dye-sensitized solar cell of claim 1, wherein the first electron collector grains and the second electron collector grains comprise titanium oxide.

7. The dye-sensitized solar cell of claim 1, wherein the first electron collector grains and the second electron collector grains are formed by coating a paste on the first electrode, the paste including first precursor grains which have a diameter or diameters within the first diameter range and second precursor grains which have a diameter or diameters within the second diameter range, the first precursor grains and the second precursor grains comprising titanium oxide; and
by sintering the paste after the coating.

8. The dye-sensitized solar cell of claim 1, wherein
the dye has an excited state and a ground state,
the dye in the excited state has a higher energy level than the electron collector, and
the dye in the ground state has a lower energy level than the electron collector.

9. The dye-sensitized solar cell of claim 1, further comprising a catalyst layer provided on the second electrode.

10. A dye-sensitized solar cell comprising:
a first substrate;
a second substrate which faces the first substrate;
a first electrode formed on a first surface of the first substrate, the first surface facing a second surface of the second substrate;
an electron-collector/dye layer provided on the first electrode;
a catalyst layer provided on the second surface, the catalyst layer having a diffusion/reflection surface which faces the first surface; and
an electrode donor provided between the electron-collector/dye layer and the catalyst layer.

11. The dye-sensitized solar cell of claim 10, wherein
the second surface includes a rough surface, and
the diffusion/reflection surface is formed so that a shape of the diffusion/reflection surface corresponds to a shape of the rough surface.

12. The dye-sensitized solar cell of claim 11, wherein the rough surface is a frosted surface, chemical etched surface, and/or sandblasted surface.

13. The dye-sensitized solar cell of claim 10, further comprising a foundation layer which is provided between the second substrate and the catalyst layer, the foundation layer being in contact with the catalyst layer.

14. The dye-sensitized solar cell of claim 13, wherein
the catalyst layer comprises platinum, and
the foundation layer comprises titanium.

15. The dye-sensitized solar cell of claim 10, wherein the electron-collector/dye layer includes an electron collector comprising titanium oxide.

16. The dye-sensitized solar cell of claim 15, wherein
the dye has an excited state and a ground state,
the dye in the excited state has a higher energy level than the electron collector, and
the dye in the ground state has a lower energy level than the electron collector.

17. A dye-sensitized solar cell comprising:
a first electrode;
a second electrode which faces the first electrode;
an electron-collector/dye layer provided on a first surface of the first electrode, the first surface facing a second surface of the second electrode, the electron-collector/dye layer including an electron collector and dye;
a catalyst layer provided on the second surface, the catalyst layer having a diffusion/reflection surface which facing the first surface; and
an electron donor provided between the electron-collector/dye layer and the catalyst layer.

18. The dye-sensitized solar cell of claim 17, wherein the electron collector comprises first electron collector grains which have a diameter or diameters within a first diameter range and second electron collector grains which have a diameter or diameters within a second diameter range, a minimum value of the second diameter range being greater than a maximum value of the first diameter range.

19. The dye-sensitized solar cell of claim 18, wherein
the first electron collector grains are configured to absorb the dye, and
the second electron collector grains are configured to transfer electrons discharged from the dye to the first electrode.

20. The dye-sensitized solar cell of claim 19, wherein the second electron collector grains have an average diameter which is ten times or more greater than an average diameter of the first electron collector grains.
